(19) United States
(12) Patent Application Publication
(10) Pub. No.: US 2008/0283841 A1
(43) Pub. Date: Nov. 20, 2008

(54) TFT SUBSTRATE AND MANUFACTURING METHOD, AND DISPLAY DEVICE WITH THE SAME

(75) Inventor: Kazushi YAMAYOSHI, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/868,088

(22) Filed: Oct. 5, 2007

(30) Foreign Application Priority Data
Oct. 18, 2006 (JP) 2006-283731

(51) Int. Cl. H01L 29/40; H01L 21/70

(52) U.S. Cl. 257/71; 438/239; 257/E21.535; 257/E29.128

(57) ABSTRACT

In forming a TFT and a storage capacitance element, whereas sharing with each other the conductive film and the insulation film, which are components of the TFT and the storage capacitance element, contributes to improving production efficiency, it is difficult to obtain a storage capacitance element that is optimized independently of the TFT. A TFT substrate provided with a TFT and a storage-capacitance element according to the present invention is characterized in that the storage-capacitance element is obtained that includes an electrically conductive film and an insulation film each being different from those used in the TFT. Furthermore, in order to form such a structure, a method of manufacturing the TFT substrate is provided that achieves both flexibility in design and efficiency in production without need for addition of any photolithography processes.

### BACKGROUND OF THE INVENTION

1. Field of the Invention

The present invention relates to an active-matrix thin-film-transistor substrate formed with thin film transistors and storage-capacitance elements, and to a structure of and a manufacturing method of a display device using the substrate.

2. Description of the Prior Art

Usually, pixels are formed in the display area of a display device, and displaying is performed by applying a signal voltage to a designated pixel. The designation is performed by a thin-film-transistor (hereinafter abbreviated as TFT) connected to each pixel with an auxiliary capacitor being added in order to keep the signal voltage constant during a designating period. To be more specific, the signal voltage applied to each pixel in the display device in synchronism with a given scan timing needs to be sufficiently held until the next scan timing. Holding the signal voltage for the pixel is fulfilled by charging a storage-capacitance element having a desired capacity.

A TFT is composed of a semiconductor layer such as a silicon film formed on an insulation substrate, a gate electrode, source drain wiring, an electrically conductive film such as a transparent conductive film, and an insulation film. In manufacturing a TFT substrate, while a TFT and a storage-capacitance element may be formed individually, it is advantageous to form them simultaneously from a viewpoint of production efficiency. That is, the storage-capacitance element may be sometimes formed concurrently using the same materials as those for the semiconductor layer, the conductive film, and the insulation film with which the TFT is constituted. For example, a technology has been disclosed in which a lower electrode, a dielectric insulation layer, and an upper electrode of a storage-capacitance element are formed using the same materials as those for a semiconductor layer, a gate insulation film, and a gate electrode of a TFT, respectively, (refer to FIG. 5 in Japanese Patent Laid-Open No. 2001-296550, and FIG. 1 in Japanese Patent laid-Open No. H06-235939). Furthermore, another technology has also been disclosed in which a lower electrode, a dielectric insulation layer, and an upper electrode of a storage-capacitance element are formed using the same materials as those for a gate electrode, an interlayer insulation film that covers the gate electrode, and a source electrode of a TFT, respectively, (refer to FIG. 1 in Japanese Patent Laid-Open No. 2004-241750).

On the other hand, another technology has also been disclosed in which layers different from a conductive layer and an insulation layer, which are main components of a TFT, are additionally formed as layers constituting a dielectric insulation layer and an upper electrode of a storage-capacitance element (refer to FIG. 4 in Japanese Patent Laid-Open No. 2001-305581).

Recent years have seen the development of display devices for high definition. For that reason, efforts have been made to enlarge the aperture ratio by narrowing the light-shield area of each pixel, which is an area unable to display. However, in TFT substrates also, the electrode area of a storage-capacitance element occupies most of the light-shield area, so that reduction of the electrode area has now become an important problem. On the other hand, the storage-capacitance element is required to have a desired capacity as explained above. Accordingly, there is a limit to reducing the electrode area based on the premise that the same layer is used for both the storage-capacitance element and the TFT, which is explained below.

In order to reduce the capacitor electrode area, it is required to form a dielectric layer either using a material having a high relative permittivity or making the layer as thin as possible to secure a desired capacity. While a silicon nitride (SiNx) film is used as a material of a relatively high relative-permittivity, the film has a problem with warpage due to an increase in the film stress. Making thin the film thickness of the dielectric layer of the storage-capacitance element enables its capacitance to increase; however, it may result in decrease in withstand voltage and increase in stray capacitance due to the small film thickness, in a case of the dielectric layer being shared with an interlayer insulation film in other portions such as TFTs and areas between wiring. These phenomena also give rise to problems such as of increase in short circuit failure and deterioration in electric characteristics.

On the premise that the dielectric layer of the storage-capacitance element is formed of the same material and with the same thickness as those of interlayer insulation films of TFTs, which is advantageous for production efficiency, the storage-capacitance element area, however, is difficult to be reduced. Accordingly, improvement of the aperture ratio is limited. Moreover, forming an additional layer having a thickness and a material most suited to the storage-capacitance element, as a matter of course, causes reduction in production efficiency. The root cause of these problems is resulted from reduction of flexibility in the design by the fact that the same material is used in forming both the TFT and the storage-capacitance element, which although improves their production efficiency, as described above. Hence, a method has been needed that eliminates these adverse effects without reducing production efficiency.

### SUMMARY OF THE INVENTION

A TFT substrate provided with TFTs and storage-capacitance elements according to the present invention is characterized in that the storage-capacitance elements include an electrically conductive film and an insulation film that are different from those used for the TFTs.

According to the present invention, a TFT substrate can be obtained that is provided with storage-capacitance elements having an optimum material and an optimum film thickness without restricting efficiency in production and flexibility in design.

### BRIEF DESCRIPTION OF THE DRAWINGS

FIG. 1 is a schematic plane view illustrating a configuration of a TFT substrate according to Embodiment 1;

FIGS. 2A and 2B are a plane view and a cross-sectional view, respectively, illustrating a structure of one of pixels on the TFT substrate according to Embodiment 1;

FIGS. 3A and 3B are a plane view and a cross-sectional view, respectively, illustrating a structure of the pixel on the TFT substrate according to Embodiment 1, having been processed by the first photolithography;

FIGS. 4A and 4B are a plane view and a cross-sectional view, respectively, illustrating a structure of the pixel on the TFT substrate according to Embodiment 1, having been processed by the second photolithography;

FIGS. 5A and 5B are a plane view and a cross-sectional view, respectively, illustrating a structure of the pixel on the TFT substrate according to Embodiment 1, having been processed by three-layer etching;

FIGS. 6A and 6B are a plane view and a cross-sectional view, respectively, illustrating a structure of the pixel on the TFT substrate according to Embodiment 1 at the stage when a resist-mask has been thinned uniformly;

FIGS. 7A and 7B are a plane view and a cross-sectional view, respectively, illustrating a structure of the pixel on the TFT substrate according to Embodiment 1 at the stage when a gate electrode has been formed;

FIGS. 8A and 8B are a plane view and a cross-sectional view, respectively, illustrating a configuration of the pixel on the TFT substrate according to Embodiment 1 at the stage when etching has been performed after processed by the third photolithography;

FIGS. 9A and 9B are a plane view and a cross-sectional view, respectively, illustrating a structure of the pixel on the TFT substrate according to Embodiment 1 at the stage when contact-holes have been formed after processed by the fourth photolithography;

FIGS. 10A and 10B are a plane view and a cross-sectional view, respectively, illustrating a structure of the pixel on the TFT substrate according to Embodiment 1 at the stage when a transparent conductive film has been etched after processed by the fifth photolithography; and

FIGS. 11A and 11B are a plane view and a cross-sectional view, respectively, illustrating a configuration of one of pixels on the TFT substrate according to another embodiment.

### DETAIL DESCRIPTION OF THE PREFERRED EMBODIMENT

### Embodiment 1

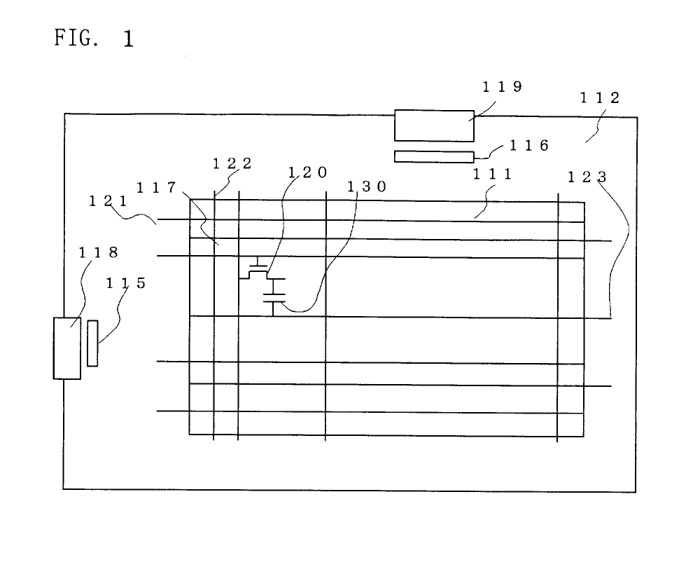

First of all, an explanation is made with reference to FIG. 1 on an active-matrix type display device that a thin-film-transistor substrate (hereinafter, abbreviated as TFT substrate) according to the present invention is applied to. FIG. 1 is a schematic plane view illustrating a configuration of the TFT substrate used in the display device. While the display device according to the invention will be explained using a liquid-crystal display device as an example, it is only an exemplification. The invention can also be applied to a flat panel display device such as an organic electroluminescent display device.

The display device according to the invention is provided with a TFT substrate 110. The TFT substrate 110, which is, for example, a TFT array substrate, has a display area 111 and a peripheral area 112 that surrounds the display area 111. In the display area 111, a plurality of parallel gate wirings (scanning signal lines) 121 and a plurality of parallel source wirings (displaying signal lines) 122 are formed so as to cross over each other orthogonally, so that areas enclosed by adjacent two of the gate wirings 121 and adjacent two of the source wirings 122 become pixels 117. Accordingly, the pixels 117 are arranged in a matrix form in the TFT substrate 111. Moreover, storage-capacitor wirings 123 are formed across the pixels 117 in parallel to the gate wirings 121.

Furthermore, a scanning-signal drive circuit 115 and a display-signal drive circuit 116 are provided in the peripheral area 112 of the TFT substrate 110. The gate wirings 121 are extended from the display area 111 to the peripheral area 112, to be connected with the scanning-signal drive circuit 115 at the edge of the TFT substrate 110. The source wirings 122 are also extended from the display area 111 to the peripheral area 112, to be connected with the display-signal drive circuit 116 at the edge of the TFT substrate 110. External wirings 118 and 119, which are wiring boards such as flexible printed circuit (FPC) boards, are connected with the scanning-signal drive circuit 115 and display-signal drive circuit 116, respectively, in the vicinities of the respective circuits.

Various signals are externally supplied to the scanning-signal drive circuit 115 and the display-signal drive circuit 116 through the external wirings 118 and 119. The scanning-signal drive circuit 115 supplies a gate signal (a scanning signal) to the gate wirings 121 based on a control signal from outside. By the gate signal, the gate wirings 121 are sequentially activated. The display-signal drive circuit 116 supplies display signals to the source wirings 122, based on display data and a control signal from outside. Thereby, the pixels 117 can be supplied with respective display voltages in accordance with the display data.

In each of the pixels 117, at least one thin film transistor (hereinafter, abbreviated as TFT) 120 and a storage-capacitance element 130 connected with the TFT 120 are formed. The TFT 120 is arranged in the vicinity of each cross-point of the source wirings 122 and the gate wirings 121. When the TFT 120, which is a switching element, turns on by the gate signal from one of the gate wirings 121, the TFT 120 thereby supplies a display voltage from one of the source wirings 122 to a pixel electrode connected to its drain electrode. An electric field in accordance with the display voltage is resultantly produced between the pixel electrode and its counter electrode. On the other hand, the storage-capacitance element 130 is electrically connected not only to the TFT 120 but also to the counter electrode through one of the storage-capacitor wirings 123. As a result, the storage-capacitance element 130 is connected in parallel between the pixel electrode and the counter electrode.

Moreover, an orientation film (not shown) is formed on the surface of the TFT substrate 110. Furthermore, a counter substrate, which is, for example, a color filter substrate, is disposed opposing the TFT substrate 110 on the viewing side. On the counter substrate, a color filter, a black matrix (BM), a counter electrode, an orientation film and the like are formed. There may be a case in which the counter electrode is disposed on the TFT substrate 110 side. A liquid crystal layer is held between the TFT substrate 110 and the counter substrate, that is, a liquid crystal is injected into therebetween. On the outer surfaces of the TFT substrate 110 and the counter substrate, polarization plates, a phase difference plate, and the like are provided. Moreover, a backlight unit is disposed behind the liquid crystal display panel opposite from the viewing side.

The liquid crystal is driven by the electric field between the pixel electrode and the counter electrode, that is, the alignment direction of the liquid crystal between the substrates is varied. Light passing through the liquid crystal layer is thereby changed in its polarization state. To be more specific, light from the backlight unit is linearly polarized by being passed through the polarization plate on the array substrate side, and the linearly polarized light is varied in its polarization state by being passed through the liquid crystal layer.

The amount of the light passing through the polarization plate on the counter substrate resultantly varies according to the polarization state. That is, the transmitted light passed through the liquid-crystal display panel from the backlight unit is varied in amount by passing through the polarization plate on the view side. Accordingly, by varying the display voltage, the amount of the light having been passed through the polarization plate on the view side, that is, by varying on a pixel basis the display voltage, a desired image can be displayed. In the series of these operations, the storage-capacitance element 130 serves to hold the display voltages by producing the electric field parallel to that between the pixel electrode and the counter electrode.

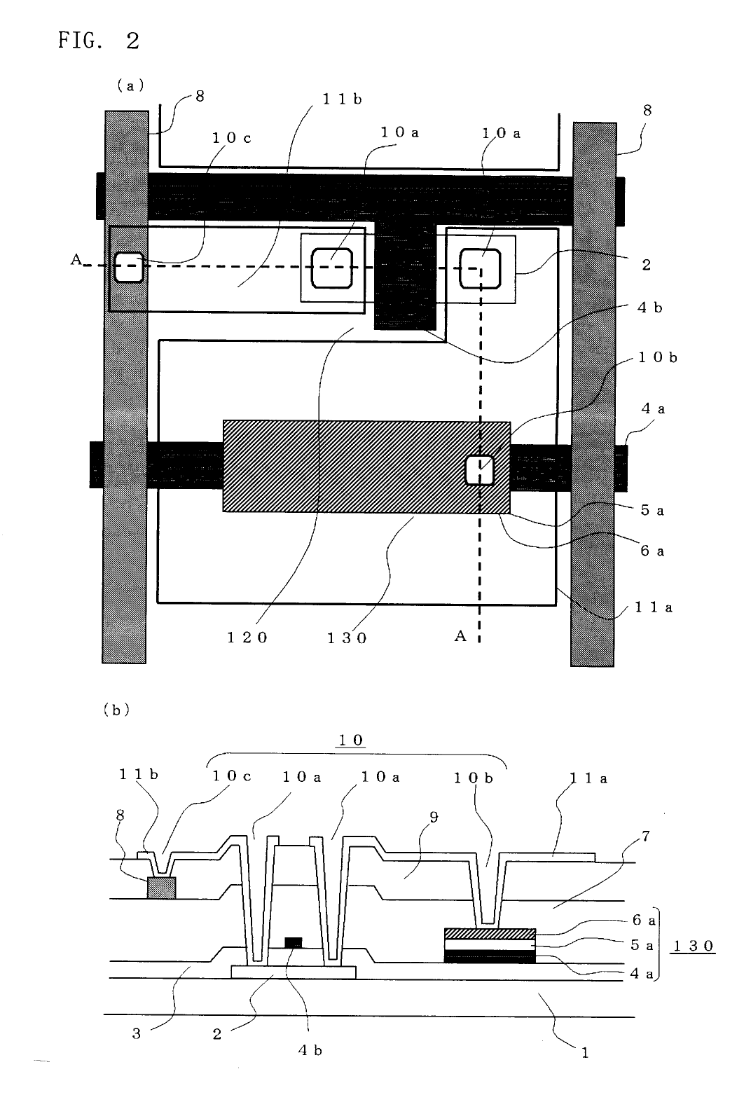

Next, an explanation will be made below with reference to FIGS. 2A and 2B on a configuration of the TFTs 120 and the storage-capacitance elements 130 both provided on the TFT substrate 110 according to the present embodiment. FIG. 2A is a plane view illustrating one of the pixels, also showing the TFT 120 and the storage-capacitance element 130, in a pixel area of the display device. A cross-sectional view taken along “A-A” broken line shown in FIG. 2A, that is a cross-sectional view of the TFT 120 and the storage-capacitance element 130, is shown in FIG. 2B. A semiconductor layer 2 made of poly-silicon or the like is formed on a substrate 1, and a gate insulation film 3 is formed so as to cover the substrate 1 and the semiconductor layer 2. A gate electrode 4b and a first capacitor electrode 4a of the storage-capacitance element 130, both electrodes being conductive films formed as the same layer, are formed on the gate insulation film 3. The storage-capacitance element 130 is composed of the first capacitor electrode 4a, a dielectric layer 5a formed thereon, and a second capacitor electrode 6a formed on the dielectric layer 5a. The dielectric layer 5a and the second capacitor electrode 6a are processed in an identical pattern so as to have approximately the same form.

An interlayer insulation film 7 is formed so as to cover the gate electrode 4b and the storage-capacitance element 130. A source drain wiring 8 is formed on the interlayer insulation film 7, and an insulation film 9 is formed so as to cover the source drain wiring 8 and the interlayer insulation film 7. Furthermore, contact-holes 10 are opened: first contact-holes 10a that reach the surface of the semiconductor layer 2 are formed penetrating the insulation film 9, the interlayer insulation film 7, and the gate insulation film 3; a second contact-hole 10b that reaches the surface of the second capacitor electrode 6a is formed penetrating the insulation film 9 and the interlayer insulation film 7; and a third contact-hole 10c that reaches the source drain wiring 8 is formed penetrating the insulation film 9.

A transparent conductive film 11b that is a connection electrode is formed on the insulation film 9 to connect the semiconductor layer 2 with the source drain wiring 8 through one of the first contact-holes 10a and the third contact-hole 10c, and a transparent conductive film 11a that is the pixel electrode is also formed on the insulation film 9 to connect the semiconductor layer 2 with the second capacitor electrode 6a through the other of the first contact-holes 10a and the second contact-hole 10b.

In this embodiment, the second capacitor electrode 6a of the storage-capacitance element 130 is formed as another layer that is different from those of the source drain wiring 8 and the pixel electrode 11a; and the dielectric layer 5a of the storage-capacitance element 130 is also formed as another layer that is different from insulation layers such as the interlayer insulation film 7 that is a constituent of the TFT 120. Moreover, the second capacitor electrode 6a and the dielectric layer 5a are not formed in the TFT 120 because they are in the same pattern for the storage-capacitance element 130. Therefore, materials, thicknesses, and the likes necessary for the second capacitor electrode 6a and the dielectric layer 5a from the design standpoint, can be freely determined independently of requirements of a conductive film and an insulation film for the TFT. Moreover, according to the embodiment, no increase in the number of photolithography processes is needed in forming such a structure, which does not reduce the production efficiency at all. As for this point, it will be disclosed in detail in the following explanation on a method of manufacturing the TFT substrate.

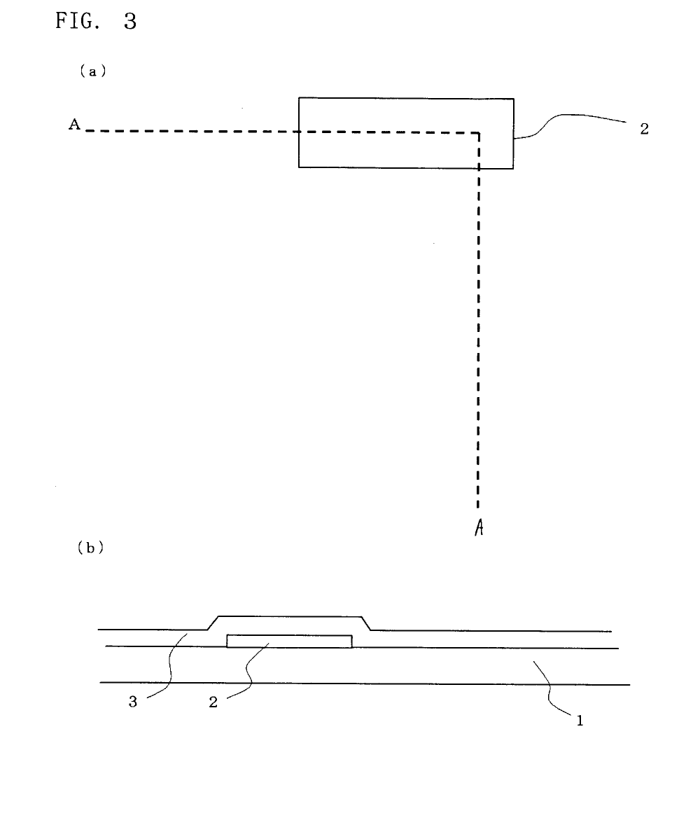

An explanation is made with reference to FIGS. 3 through FIGS. 10 on a method of manufacturing the TFT substrate provided with the TFT and the storage-capacitance element according to the embodiment. FIG. 3A is a top plane view of the pixel at the stage when the gate insulation film 3 has been formed, and a cross-sectional view taken along “A-A” broken line is shown in FIG. 3B. Firstly, in FIG. 3B, an amorphous silicon film is formed as a semiconductor film on the substrate 1 made of glass, quartz, plastic or the like by a chemical vapor deposition (CVD) or the like. Then, the silicon film is crystallized into the semiconductor layer 2 by being irradiated with an excimer laser. Here, the semiconductor layer 2 is patterned as shown in FIG. 3A by applying etching thereto after processed by the first photolithography. In the pattering, by setting sufficiently small the taper angle of the cross-sectional shape of the photosensitive resist-mask formed by a photolithography, the semiconductor layer 2 is desirably formed, with its taper angle being approximately 30 degrees, which is not shown in the figure.

While the semiconductor film is formed directly on the substrate 1 in the embodiment, a semiconductor film may be formed after an inorganic insulation film of SiO₂, SiN, or the like has been formed. That is, after the inorganic insulation film and the semiconductor film are successively formed on the substrate 1, only the semiconductor film may be patterned as described above. In this case, an effect is brought about that can prevent contaminants from migrating from the substrate into the semiconductor film due to the existence of the inorganic insulation film therebetween.

After that, the gate insulation film 3 is formed so as to be in contact with the semiconductor layer 2 as shown in FIG. 3B by a CVD method. As the gate insulation film 3, SiO₂ or SiN is frequently used. Since the gate insulation film 3 has a great influence on electric characteristics of the thin film transistor, the insulation film thickness, in particular, is subject to extremely precise control, and is 70 to 100 nm in normal cases.

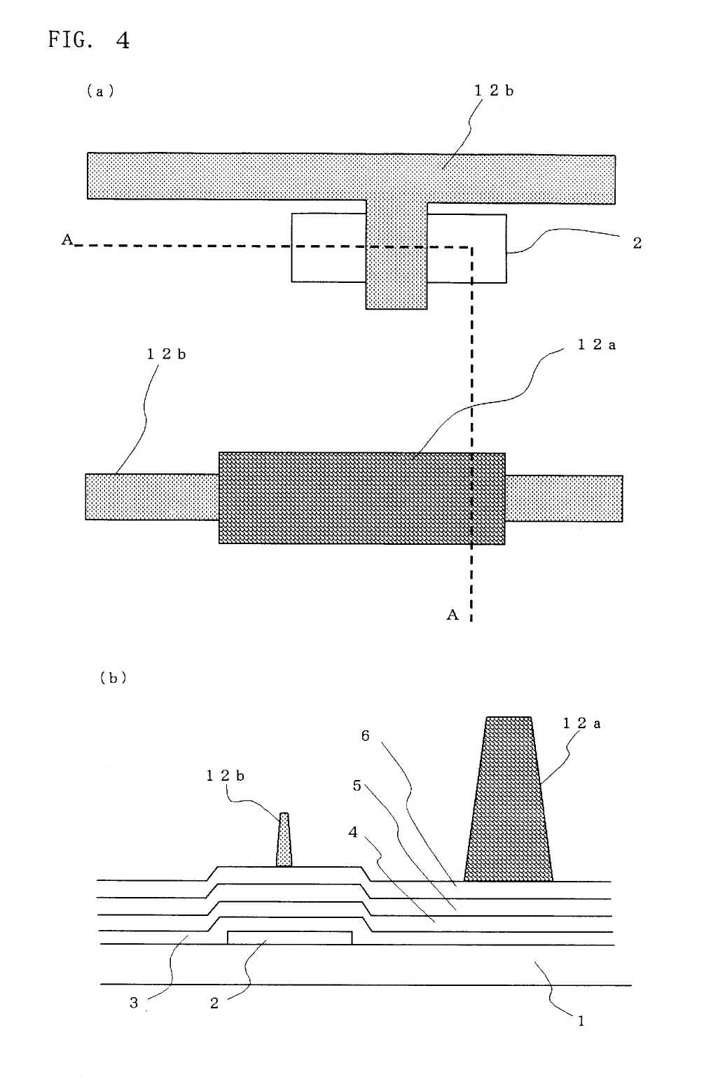

Next, after a first metal layer 4, an insulation layer 5, and a second metal layer 6 are formed by a well-known method, a resist-mask 12 is formed by the second photolithography. A top plane view and a cross-sectional view of the pixel at this stage are shown in FIG. 4A and FIG. 4B, respectively.

The first metal layer 4 is a conductive layer composed of a mono-layer or a laminated structure with base materials of Mo, Cr, W, or Al formed by a vapor deposition method or a spattering method, for forming the gate electrode 4b, the first capacitor electrode 4a, gate wirings that are not shown, and the like. For forming the first capacitor electrode 4a, there is no particular limitation on the first metal layer 4 as long as it is a conductive layer. However, since the first metal layer 4 is also used for the gate electrode 4b, the gate wirings, and the like that are formed later on the semiconductor layer 2 in the thin film transistor 120, the metal layer is limited to such a material that etching workability, electrical conductivity, and the like are taken into account.

The insulation layer 5 is an insulation layer to become the dielectric layer 5a of the storage-capacitance element 130 and is made of SiO₂ or SiN formed by a CVD method or the like. The material and the thickness of the insulation layer 5 are determined so that a desired capacitance Cs is obtained by optimizing the relative permittivity e of the dielectric layer 5a, the required film thickness d thereof, and the required capacitor electrode area A taking into account the aperture ratio of the pixel and the like. Specifically, the capacitance Cs is calculated by the following formula:

Cs=ε*A/d.

While SiO₂ and SiN given above have relative permittivities of 3.9 and 6.7, respectively, a material for the insulation layer 5 is not limited to these. For example, if there is no problem with etching workability, an extremely thin oxide insulation film of 10 through 50 nm may be formed as the insulation layer 5 on the surface of the first metal layer 4 by an anodic oxidation method, to form the second metal layer 6 thereafter. Alumina may be used as the oxide insulation film.

The second metal layer 6 is a conductive layer that is a metal film formed by a spattering method or a vapor deposition method, for forming the second capacitor electrode 6a of the storage-capacitance element 130. A material of Mo or Cr is desirable for the metal film due to easiness of etching. While the film thickness is desirably as thin as possible from the viewpoint of etching selectivity for the gate insulation film 3, which is described later, the thickness is appropriately determined because the film thickness is needed at least to serve as an ion-implantation mask. In the embodiment, a Mo film is formed so as to be 100 nm in thickness.

Next, an explanation is made on resist-masks 12a and 12b shown in FIG. 4B. As can be seen from FIG. 2B showing the TFT 120 and the storage-capacitance element 130, since at least the gate electrode 4b, the first capacitor electrode 4a, the dielectric layer 5a, and the second capacitor electrode 6a are necessary to be formed eventually, the resist-mask 12a is formed on the area where the second capacitor electrode 6a is to be formed, and the resist-mask 12b is formed on the area extending from the first capacitor electrode 4a and on the area where the gate electrode 4b is to be formed. Moreover, as shown in FIG. 4B, the resist-mask 12a on the area corresponding to the second capacitor electrode 6a is formed thicker than the resist-mask 12b on that corresponding to the gate electrode 4b.

In order to thus vary the film thickness of the resist from area to area, a well-known manufacturing method called “gray-tone” or “half-tone” can be employed. In a case of a positive-type resist, it has a tendency that its residual film thickness increases with decreasing the amount of irradiation light in a photolithography. Accordingly, reducing the amount of light irradiating the area corresponding to the gate electrode 4b than that irradiating the area corresponding to the second capacitor electrode 6a, allows to form the resist-masks 12a and 12b as shown in FIG. 4B. Particularly as for the resist-mask 12a on the area where the second capacitor electrode 6a is formed, it should be noted that the mask is required to have a film thickness to the extent of being able to serve as a mask even after being subject to an ashing process and a plurality of etching processes that are described later. Incidentally, the gate wirings and terminal portions, which are not shown in the figures, are irradiated with the same amount of light as that the resist-mask 12b is irradiated with.

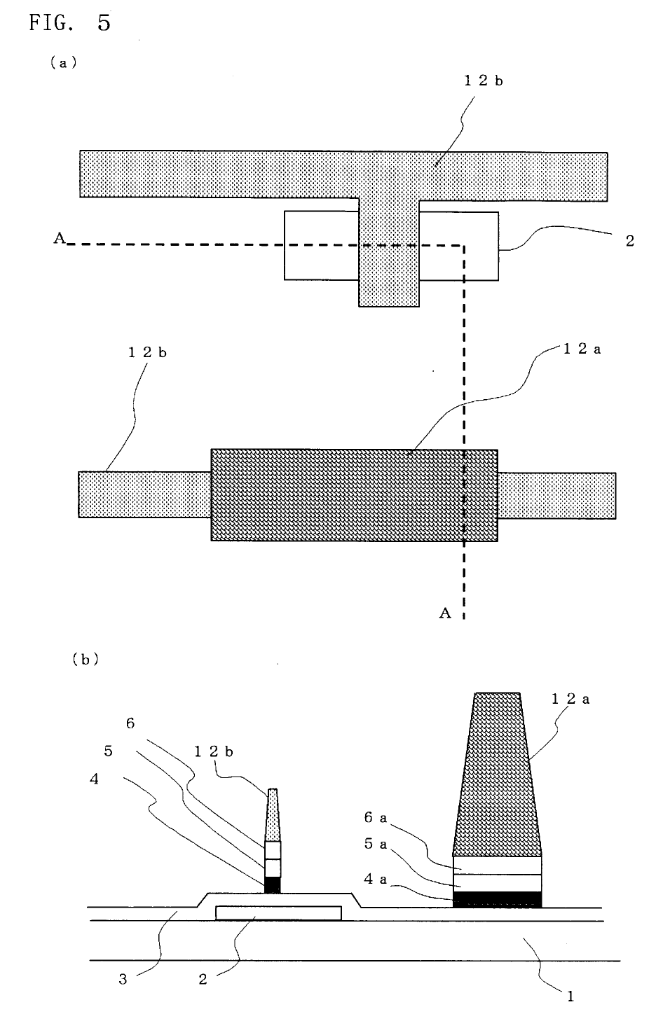

After that, the areas not covered with the resist-masks 12a and 12b are etched continuously layer by layer in the order of the second metal layer 6, the insulation layer 5, and the first metal layer 4. These three layers may be etched together at once. FIGS. 5A and 5B show a top plane view and a cross-sectional view of the pixel at this stage, respectively. In the etching process, since the resist-mask pattern is not changed, the three layers are formed in the same pattern.

Next, an ion implantation is performed, which is not shown in the figures, using an electrically conductive contaminant such as boron. While the boron reaches the semiconductor layer 2 through the gate insulation film 3, to form a source drain region in the semiconductor layer 2, the region beneath the gate electrode 4b is not implanted with the boron because the gate electrode 4b serves as a mask. Thus, a channel region is formed in the semiconductor layer 2 beneath the gate electrode 4b. Incidentally, implantation of boron as described above forms a P-MOS TFT, whereas implantation of phosphorus forms an N-MOS TFT.

Next, the resist-masks 12a and 12b are uniformly thinned by ashing using oxygen, and then the ashing is stopped when the resist-mask 12b on the gate electrode 4b has disappeared. Regarding ashing, depending on apparatus, an ashing rate is preferably not so large in order to perform ashing as uniform as possible and to easily control the ashing amount. The ashing in the embodiment is performed at a rate of 600 nm/min. under the condition of an oxygen flow rate of 150 standard-cc/min.. Incidentally, while oxygen alone is used as an ashing gas in the embodiment, nitrogen or a fluorinated gas may be added thereto.

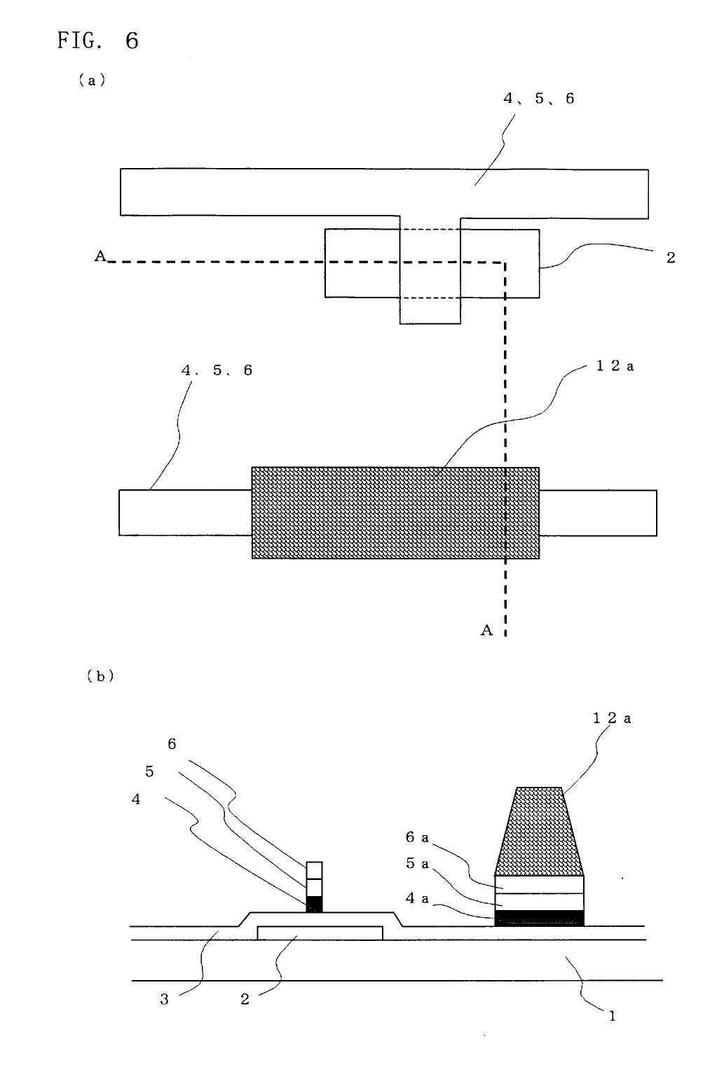

FIGS. 6A and 6B show a state after the ashing is completed. Whereas part of the second metal layer 6 is exposed due to the removal of the resist-mask 12b on the gate electrode 4b, the resist-mask 12a remains only on the second capacitor electrode 6a.

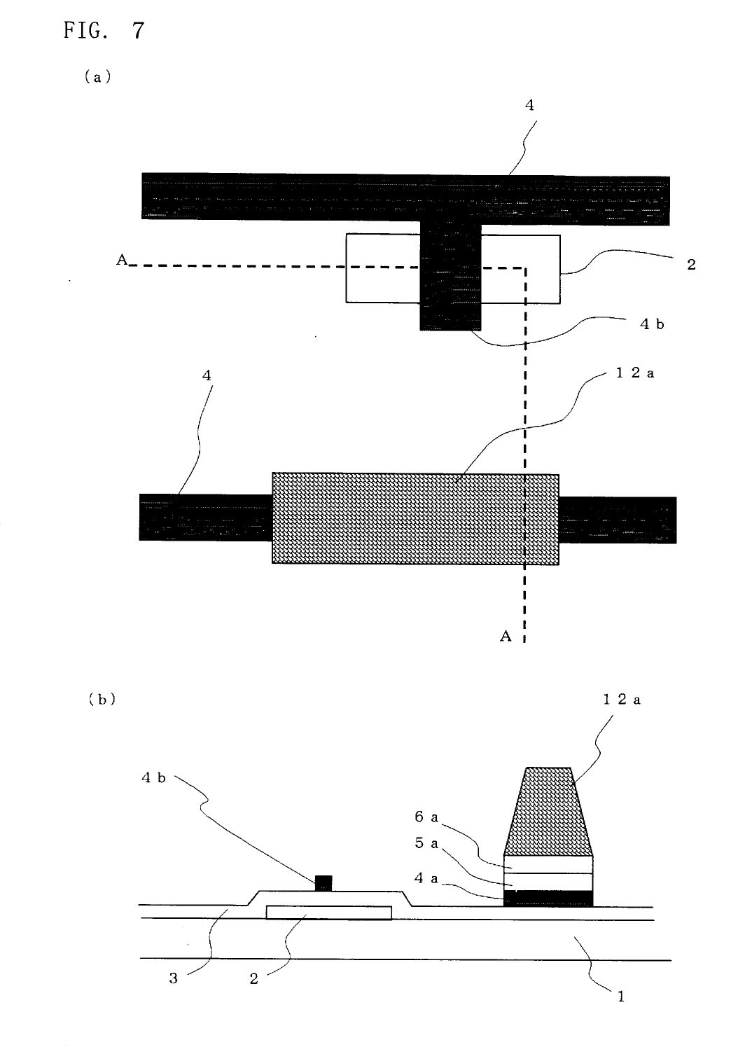

After that, an exposed part of the second metal layer 6 other than the second capacitor electrode 6a, that is, part of the second metal layer 6 remaining on the gate electrode 4b is removed by etching. Furthermore, part of the insulation layer 5 is also removed by etching. A state at this stage is shown in FIGS. 7A and 7B. Since the gate insulation film 3 is also exposed during the etching, a high selective etching is desirably employed so as to etch the gate insulation film 3 as little as possible. The gate electrode 4b is exposed by the etching on the one hand, the second capacitor electrode 6a is protected by the resist-mask 12a on the other hand, so that the storage-capacitance element 130 also remains intact in its structure. After that, the resist-mask 12a on the second capacitor electrode 6a is removed by ashing or the like.

Next, the interlayer insulation film 7 is formed. A SiO₂ film or SiN film formed by a CVD method is excellently suitable for the interlayer insulation film 7. An annealing process may be performed thereafter in order to activate the conductive contaminant such as boron having been implanted into the semiconductor layer 2.

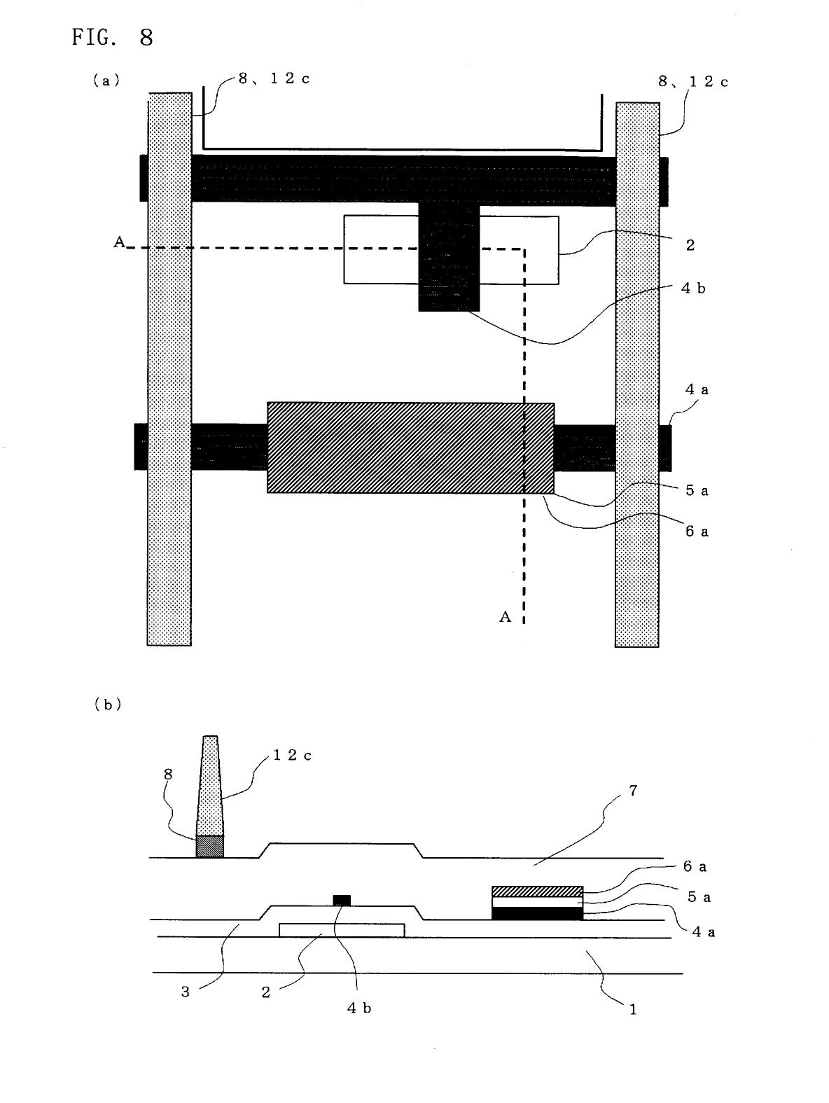

A third metal layer is further formed on the interlayer insulation film 7 by a spattering method or the like. Then, a resist-mask 12c coated thereon is formed by the third photolithography. After that, the source drain wiring 8 is formed by etching the third metal layer. A top plane view and a cross-sectional view of the structure at this stage are shown in FIGS. 8A and 8B, respectively. A laminated structure of an aluminum film or an aluminum alloy film is recommended to be employed for the third metal layer because such films have an effect reducing wiring resistance. Incidentally, the resist-mask 12c is removed by a well-known method such as ashing.

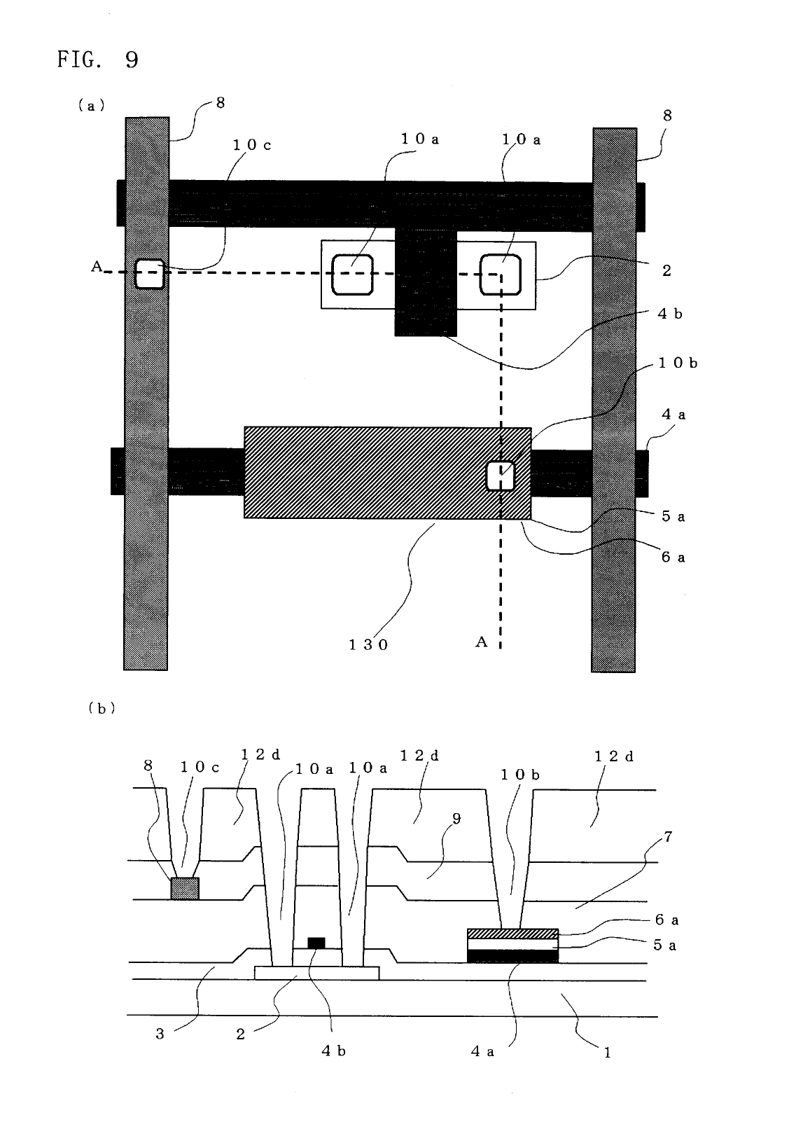

After that, the insulation film 9 is formed so as to cover the source drain wiring 8 and the interlayer insulation film 7. Then, the resist-mask 12d coated on the insulation film 9 is formed by the fourth photolithography. The contact-holes 10a, 10b, and 10c are formed thereafter. A top plane view and a cross-sectional view of the pixel at this stage are shown in FIGS. 9A and 9B, respectively.

A SiN film formed by a CVD method is used for the insulation film 9. The contact-holes 10 are formed by dry-etching using a fluorinated gas such as carbon tetrafluoride (CF₄) with an etching rate of 70 nm/min. after the resist-mask 12d having openings as shown in FIG. 9B is formed. The contact-holes 10a that are the first contact-holes reaching the semiconductor layer 2, the contact-hole 10b that is the second contact-hole reaching the second capacitor electrode 6a, and the contact-hole 10c that is the third contact-hole reaching the source drain wiring 8, are shown as contact-holes 10 in FIG. 9B. The contact-holes 10a are formed by etching the insulation film 9, the interlayer insulation film 7, and the gate insulation film 3. Similarly, the contact-hole 10b is formed by etching the insulation film 9 and the interlayer insulation film 7, and the contact-hole 10c, by etching the insulation film 9. Other contact-holes are properly formed as necessary to obtain electrical connection with the gate electrode 4b, the gate wirings and the terminal portions, and the first capacitor electrode 4a, which are not shown in the figure. The resist-mask 12d is removed by a well-known means after the contact-holes 10a, 10b, and 10c have been formed.

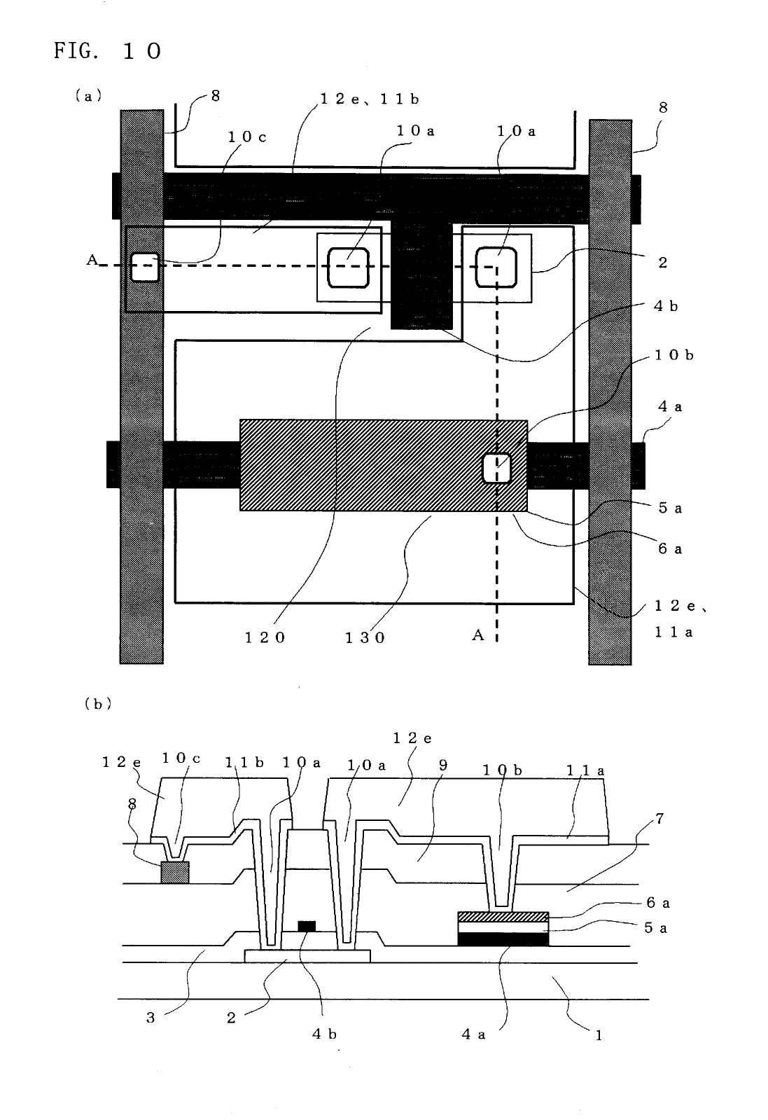

After that, the transparent conductive film 11 is formed. The resist-mask 12e coated thereon is formed thereafter by the fifth photolithography, and then the transparent conductive film 11 is etched. A top plane view and a cross-sectional view of the pixel at this stage are shown in FIGS. 10A and 10B, respectively. While, in the embodiment, an amorphous indium-tin oxide (ITO) film is formed as the transparent conductive film 11 by a spattering method or a vapor deposition method, an indium-zinc oxide (IZO) film or an indium-tin-zinc oxide (ITZO) film may be formed as the film.

The resist-mask 12e has a pattern such as to connect the pixel electrode with the contact-holes corresponding thereto, and to connect the connection electrode with the contact-holes corresponding thereto. Thereby, as shown in FIG. 2B, the transparent conductive film 11a is formed, by removing the ITO film by etching, as the pixel electrode that extends so as to connect the second capacitor electrode 6a with the semiconductor layer 2 through the contact-holes 10a and 10b. The transparent conductive film 11b is also formed similarly as the connection electrode that connects the semiconductor layer 2 with the source drain wiring 8 through the contact-holes 10a and 10c. Then, the resist-mask 12e is removed by a well-known means. By the processes described above, the TFT substrate can be formed that is provided with the TFT 120 and the storage-capacitance element 130 according to the embodiment.

In the embodiment, after the second photolithography, two processes are performed: the resist-masks 12a and 12b are uniformly thinned by the ashing process; and then the etching process is performed in the state of only the resist-mask 12a remaining. By this method, the insulation film different from that of the TFT 120 can be formed in the storage-capacitance element 130 without adding any photolithography processes. That is, the dielectric layer 5a made of a suitable material for and having an optimum film thickness for the storage-capacitance element 130 can be formed without sacrificing production efficiency and flexibility in design. Moreover, the second capacitor electrode 6a of the storage-capacitance element 130 is also different from the electrode wiring used for the TFT 120, which allows a suitable material and an optimum thickness to be selected for the storage-capacitance element 130.

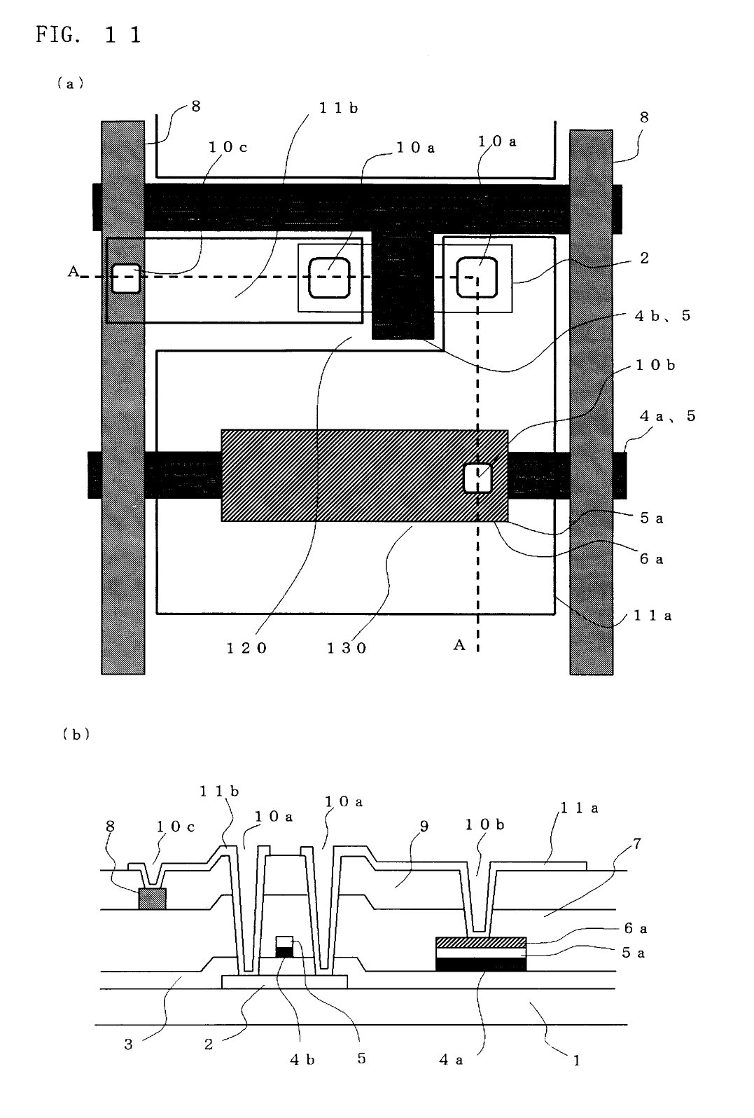

The manufacturing method disclosed in the present embodiment is not limited to that as described, but may be altered within the scope of the effect being brought about. While, in the embodiment, the explanations have been made on the manufacturing method in which not only the second metal layer 6 but also the insulation layer 5 on the gate electrode 4b are removed as shown in FIG. 7B, only the insulation layer 5 may be left intact by stopping the etching at the stage when the second metal layer 6 has been etched. The layer, not covered with the second capacitor electrode 6a, on the first metal layer 4 may also be left similarly. In this case, the possibilities are more reduced that the gate insulation layer 3 will be etched during etching the second metal layer 6, and that the resist-mask 12a will disappear, which brings about an effect extending the tolerable range of the etching condition. A top plane view and a cross-sectional view of a pixel in a TFT substrate thus formed are shown in FIGS. 11A and 11B, respectively.

Whereas the insulation layer 5 shown in FIGS. 2A and 2B is processed as the dielectric layer 5a having approximately the same form as that of the second capacitor electrode 6a, the insulation layer 5 shown in FIGS. 11A and 11B is different from that shown in FIGS. 2A and 2B in the point that it is processed so as to have the same form as those of the gate electrode 4b and of the dielectric layer 5a having approximately the same form as that of the first capacitor electrode 4a. However, the dielectric layer 5a is the same as shown in FIGS. 2A and 2B in the point that it is formed between the second capacitor electrode 6a and the first capacitor electrode 4a facing with each other.

Moreover, the manufacturing method disclosed in the embodiment is not limited to that as described, but may be appropriately added within the scope of the effect being brought about. For example, when the second metal layer 6 has been etched to be removed as shown in FIG. 6B, a low-concentration conductive contaminant may be implanted into the semiconductor layer 2 after the gate electrode 4b and the insulation layer 5 are narrowed by being etched from the lateral sides by appropriately adjusting the etching conditions such as etching time and anisotropy. The implantation forms in the semiconductor layer 2 a lightly-doped-drain (LDD) structure in which there is a low-concentration implanted region between the source drain region having been implanted with a high-concentration and the channel region with no implantation. Therefore, an effect is brought about that improves reliability of the TFT. The formation of the LDD structure, as a matter of course, needs no more addition of photolithography processes.

Furthermore, by adding one more process of a photolithography, a TFT may be formed that has a complementary metal-oxide semiconductor (CMOS) structure. That is, the CMOS structure can be formed in the second photolithography process in the embodiment by forming first a positive-channel metal-oxide semiconductor (PMOS), and then by forming a negative-channel metal-oxide semiconductor (NMOS) in a state of the PMOS being fully covered with a resist.

What is claimed is:

1. A thin film transistor substrate comprising:
a thin film transistor including
a semiconductor layer;
a gate electrode opposing the semiconductor layer in a thickness-wise direction;
a gate insulation film formed between the gate electrode and the semiconductor layer; and
a source drain wiring and a pixel electrode electrically connected with the semiconductor layer, and
a storage-capacitance element including
a first capacitor electrode of an electrically conductive film formed as the same layer as that of the gate electrode;
a dielectric layer formed on the first capacitor electrode; and
a second capacitor electrode formed on the dielectric layer in the same form as that of the dielectric layer in opposite to the first capacitor electrode through the dielectric layer, wherein
the second capacitor electrode is formed as a layer different from the source drain wiring layer and the pixel electrode layer.

2. A thin film transistor substrate as set forth in claim 1, further comprising
an interlayer insulation film formed above the gate electrode and below the source drain wiring, wherein
the dielectric layer is formed as a layer different from the interlayer insulation film.

3. A thin film transistor substrate as set forth in claim 2, further comprising:
an insulation film formed so as to cover the source drain wiring and the interlayer insulation film;
a connection electrode and the pixel electrode each formed on the insulation film;
a plurality of first contact-holes formed penetrating the insulation film, the interlayer insulation film, and the gate insulation film, to reach the semiconductor layer;
a second contact-hole formed penetrating the insulation film and the interlayer insulation film, to reach the second capacitor electrode; and
a third contact-hole formed penetrating the insulation film, to reach the source drain wiring, wherein
the source drain wiring and the semiconductor layer are electrically connected with each other by the connection electrode through the third contact-hole and one of the first contact-holes, and
the second capacitor electrode and the semiconductor layer are electrically connected with each other by the pixel electrode through the second contact-hole and the other of the first contact-holes.

4. A thin film transistor substrate as set forth in claim 1, wherein the gate electrode is formed as a layer above the semiconductor layer.

5. A thin film transistor substrate comprising:
a thin film transistor including
a semiconductor layer;
a gate electrode opposing the semiconductor layer in a thickness-wise direction;
a gate insulation film formed between the gate electrode and the semiconductor layer;
an insulation film formed on the gate electrode in the same form as that of the gate electrode; and
a source drain wiring and a pixel electrode electrically connected with the semiconductor layer, and
a storage-capacitance element including
a first capacitor electrode of an electrically conductive film formed as the same layer as that of the gate electrode;
a dielectric layer formed on the first capacitor electrode in the same form as that of the first capacitor electrode; and
a second capacitor electrode formed on the dielectric layer in the same form as that of the dielectric layer in opposite to the first capacitor electrode through the dielectric layer, wherein
the second capacitor electrode is formed as a layer different from the source drain wiring layer and the pixel electrode layer.

6. A thin film transistor substrate as set forth in claim 5, further comprising
an interlayer insulation film formed above the gate electrode and below the source drain wiring, wherein
the dielectric layer is formed as a layer different from the interlayer insulation film.

7. A thin film transistor substrate as set forth in claim 6, further comprising:
an insulation film formed so as to cover the source drain wiring and the interlayer insulation film;
a connection electrode and the pixel electrode each formed on the insulation film;
a plurality of first contact-holes formed penetrating the insulation film, the interlayer insulation film, and the gate insulation film, to reach the semiconductor layer;
a second contact-hole formed penetrating the insulation film and the interlayer insulation film, to reach the second capacitor electrode; and
a third contact-hole formed penetrating the insulation film, to reach the source drain wiring, wherein
the source drain wiring and the semiconductor layer are electrically connected with each other by the connection electrode through the third contact-hole and one of the first contact-holes, and
the second capacitor electrode and the semiconductor layer are electrically connected with each other by the pixel electrode through the second contact-hole and the other of the first contact-holes.

8. A display device comprising:
a thin film transistor substrate including
a thin film transistor having
a semiconductor layer;
a gate electrode opposing the semiconductor layer in a thickness-wise direction;
a gate insulation film formed between the gate electrode and the semiconductor layer; and
a source drain wiring and a pixel electrode electrically connected with the semiconductor layer, and
a storage-capacitance element including
a first capacitor electrode of an electrically conductive film formed as the same layer as that of the gate electrode;
a dielectric layer formed on the first capacitor electrode; and
a second capacitor electrode formed on the dielectric layer in the same form as that of the dielectric layer in opposite to the first capacitor electrode through the dielectric layer, wherein
the second capacitor electrode is formed as a layer different from the source drain wiring layer and the pixel electrode layer.

9. A display device as set forth in claim 8, wherein the thin film transistor substrate further includes
an interlayer insulation film formed above the gate electrode and below the source drain wiring, wherein
the dielectric layer is formed as a layer different from the interlayer insulation film.

10. A display device as set forth in claim 9, wherein the thin film transistor substrate further includes
an insulation film formed so as to cover the source drain wiring and the interlayer insulation film;
a connection electrode and the pixel electrode each formed on the insulation film;
a plurality of first contact-holes formed penetrating the insulation film, the interlayer insulation film, and the gate insulation film, to reach the semiconductor layer;
a second contact-hole formed penetrating the insulation film and the interlayer insulation film, to reach the second capacitor electrode; and
a third contact-hole formed penetrating the insulation film, to reach the source drain wiring, wherein
the source drain wiring and the semiconductor layer are electrically connected with each other by the connection electrode through the third contact-hole and one of the first contact-holes, and
the second capacitor electrode and the semiconductor layer are electrically connected with each other by the pixel electrode through the second contact-hole and the other of the first contact-holes.

11. A method of manufacturing a thin film transistor substrate comprising:
a step of forming a semiconductor layer made of silicon;
a step of forming a gate insulation film so as to be in contact with the semiconductor layer;
a step of laminating a first metal layer, an insulation layer, and a second metal layer, as a multi-layer film, on the gate insulation film;
a step of forming, after the multi-layer film has been patterned, a first capacitor electrode, a dielectric layer, a second capacitor electrode, and a gate electrode by etching to remove an exposed part of the second metal layer other than the second capacitor electrode;
a step of forming a source drain wiring electrically connected to the semiconductor layer; and
a step of forming a pixel electrode electrically connected to the semiconductor layer, wherein
the second capacitor electrode is formed as a layer different from those of the source drain electrode and the pixel electrode.

12. A method of manufacturing a thin film transistor substrate as set forth in claim 11 further comprising:
a step of forming an interlayer insulation film so as to cover the gate electrode, the gate insulation film, and the second capacitor electrode;
a step of forming, by patterning, the source drain wiring after a third metal layer is formed on the interlayer insulation film;
a step of forming an insulation film so as to cover the source drain wiring and the interlayer insulation film;
a step of forming first contact-holes penetrating the insulation film, the interlayer insulation film, and the gate insulation film, to reach the semiconductor layer, of forming a second contact-hole penetrating the insulation film and the interlayer insulation film, to reach the second capacitor electrode, and of forming a third contact-hole penetrating the insulation film, to reach the source drain electrode;
a step of forming a transparent electrically conductive film on the insulation film; and
a step of forming, by patterning the transparent conductive layer, a connection electrode so as to cover the third contact-hole and one of the first contact-holes, wherein
the pixel electrode is formed, at the same time as the step of forming the connection electrode, so as to cover the second contact-hole and the other of the first contact-holes.

13. A method of manufacturing a thin film transistor substrate as set forth in claim 11, wherein the step of forming, after the multi-layer film has been patterned, the first capacitor electrode, the dielectric layer, the second capacitor electrode, and the gate electrode by etching to remove the exposed part of the second metal layer other than the second capacitor electrode includes
a step of forming a resist-mask so that the mask remains on areas corresponding to the gate electrode and the first capacitor electrode, and is made thicker in an area corresponding to the second capacitor electrode than that in the other area;
a step of etching to remove the multi-layer film in an area not covered with the resist-mask after the resist-mask is formed;
a step of thinning the resist-mask uniformly so that the mask remains only on the area where the second capacitor electrode is formed; and
a step of etching to remove the second metal layer being exposed after the thinning step.
